(19) United States
(12) Patent Application Publication
(10) Pub. No.: US 2026/0063588 A1
(43) Pub. Date: Mar. 5, 2026

(54) Environmental Chemical Detection with the Optically Gated Transistor (ENVIROGT)

(71) Applicant: BOISE STATE UNIVERSITY, Boise, ID (US)

(72) Inventors: Kristy Voss, Boise, ID (US); Bamidele Ayo Omotowa, Idaho Falls, ID (US); Olaoluwa Mayowa Omotowa, Idaho Falls, ID (US)

(73) Assignee: BOISE STATE UNIVERSITY, Boise, ID (US)

(21) Appl. No.: 19/319,302

(22) Filed: Sep. 4, 2025

Related U.S. Application Data
(60) Provisional application No. 63/690,527, filed on Sep. 4, 2024.

(51) Int. Cl. G01N 27/414; H10F 30/282

(52) U.S. Cl. CPC G01N 27/4148; H10F 30/282

(57) ABSTRACT

A system may include an optoelectronic semiconductor device including a semi-conductive substrate, an insulative layer, a photo-active layer, a source electrode, and a drain electrode. The system may further include a light source configured to selectively apply light to a surface of the photo-active layer, where the light excites electron-hole pairs within the substrate and the photo-active layer enabling an electrical current to pass between the source electrode and the drain electrode, where the presence of a chemical substance in proximity to the surface of the photo-active layer alters the electrical current in the presence of the light, and where measurement of the electrical current during application of the light enables the chemical substance to be identified.

### CROSS REFERENCE TO RELATED APPLICATIONS

This application claims the benefit of, U.S. Provisional Ser. No. 63/690,527, filed Sep. 4, 2024, and entitled “Environmental Chemical Detection with Optically Gated Transistor (ENVIR-OGT),” the contents of which are incorporated by reference herein in their entirety.

### FIELD OF THE DISCLOSURE

This disclosure is generally related to the field of substance detection and, in particular, to substance detection using an electrically and optically controlled semiconductor device.

### BACKGROUND

Detection of chemical substances in the environment may be hampered by the lack of fast and reliable methods of in-field detection. As a non-limiting example, the detection of per-and polyfluoroalkyl substances (PFAS) may be difficult to detect in real-time. The currently used analytical methods, e.g., liquid chromatography tandem mass spectroscopy, may not be field deployable, may be slow and costly, and may require significant sample preparation prior to analysis. In the non-limiting example of PFAS detection, a real-time sensor would be advantageous in order to rapidly capture information about PFAS release or presence in a given location, in order to abate environmental exposure.

### SUMMARY

Disclosed is a device for identification and quantification of substances in liquid samples. The device may include an electrically and optically controlled semiconductor device that forms an optically driven electrochemical sensor to enable real-time chemical detection. The disclosed device overcomes at least one of the shortcomings of typical substance measurement devices.

In an embodiment, a system includes an optoelectronic semiconductor device including a semi-conductive substrate, an insulative layer, a photo-active layer, a source electrode, and a drain electrode. The system further includes a light source configured to selectively apply light to a surface of the photo-active layer. The light excites electron-hole pairs within the substrate and the photo-active layer enabling an electrical current to pass between the source electrode and the drain electrode. The presence of a chemical substance in proximity to the surface of the photo-active layer alters the electrical current in the presence of the light. Measurement of the electrical current during application of the light enables the chemical substance to be identified.

In some embodiments, a fluid mixture in contact with the photo-active layer includes the substance to be identified. In some embodiments, the fluid mixture includes a gas, a liquid, or a combination thereof. In some embodiments, the chemical substance includes a perfluoroalkyl substance (PFAS). In some embodiments, the chemical substance includes perfluorooctanoic, perfluoropentanoic acid, pentafluoropropionic acid, or a combination thereof. In some embodiments, the chemical substance is methanal, ethanol, Isopropyl alcohol, lead, or a combination thereof. In some embodiments, the photo-active layer comprises a germanium-based chalcogenide. In some embodiments, the photo-active layer comprises SiGe, GaSb, InAs, MoS2, WS2, GaAs, GaN, SiC, an organic-based photoactive semiconductor, or a combination thereof. In some embodiments, the semi-conductive substrate comprises silicon and the insulative layer comprises silicon dioxide. In some embodiments, the source electrode and the drain electrode comprise a conductive metal including tungsten, cadmium, aluminum, or any combination thereof. In some embodiments, the intensity of the light source is sufficient to result in a saturation voltage-current response at the optoelectronic semiconductor device. In some embodiments, the light source is configured to generate a series of pulses of the light over time.

In an embodiment, a method includes providing an optoelectronic semiconductor device comprising a semi-conductive substrate, an insulative layer, a photo-active layer, a source electrode, and a drain electrode. The method further includes applying light to a surface of the photo-active layer, wherein the light excites electron-hole pairs within the substrate and the photo-active layer enabling an electrical current to pass between the source electrode and the drain electrode. The method also includes applying a chemical substance to a surface of the photo-active layer, thereby altering the electrical current. The method includes measuring the electrical current, thereby enabling identification of the chemical substance.

In some embodiments, the method includes placing a fluid in contact with the photo-active layer, wherein the fluid includes the electrochemical substance. In some embodiments, the method includes using the light source to generate a series of pulses of the light over time. In some embodiments the method includes providing response measurements associated with the series of pulses of light to a predictive artificial intelligence system and receiving an output from the artificial intelligence system, the output identifying the chemical substance.

In an embodiment, a system includes a semi-conductive substrate, an insulative layer, a photo-active layer, and a set of source-drain-electrode pairs, forming a set of optoelectronic semiconductor devices. The system further includes a light source configured to selectively apply light to a surface of the photo-active layer. The light excites electron-hole pairs within the substrate and the photo-active layer enabling a set of electrical currents to pass through each of the set of the optoelectronic semiconductor devices. The presence of a chemical substance at an optoelectronic semiconductor device of the set of optoelectronic semiconductor devices alters an electrical current associated with the optoelectronic semiconductor device. Measurement of the electrical current enables the chemical substance to be identified.

In some embodiments, the optoelectronic semiconductor device of the set of optoelectronic semiconductor devices is configured to contact a test fluid, and wherein at least another optoelectronic semiconductor device of the set of optoelectronic semiconductor devices is configured to contact a control fluid. In some embodiments, the chemical substance includes a perfluoroalkyl substance (PFAS) and the photo-active layer includes a germanium-based chalcogenide.

### BRIEF DESCRIPTION OF THE DRAWINGS

FIG. 1 is a perspective view of an embodiment of a system for chemical detection.

FIG. 2 is a top view of an embodiment of a system for chemical detection including multiple optoelectronic semiconductor devices.

FIG. 3 is a graph depicting measurement responses for alcohols including methanol, ethanol, and isopropyl alcohol.

FIG. 4 is a graph depicting measurement responses for perfluoroalkyl substances (PFAS) including perfluorooctanoic, perfluoropentanoic acid, and pentafluoropropionic acid.

FIG. 5 is a flowchart depicting an embodiment of a method for substance identification.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the scope of the disclosure.

### DETAILED DESCRIPTION

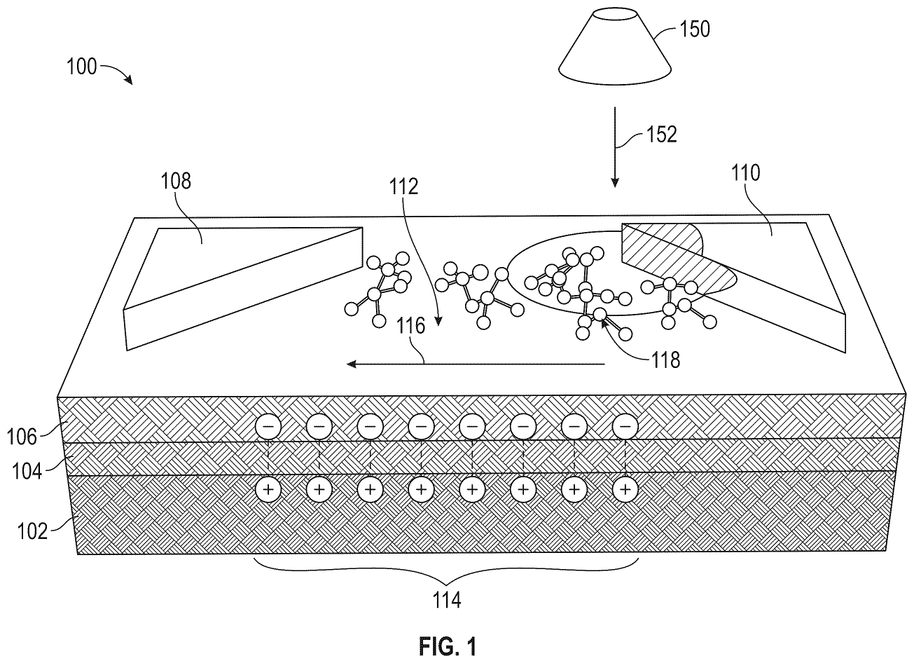

Referring to FIG. 1, an embodiment of a system 100 is depicted. The system 100 may include a semiconductive substrate 102, an insulative layer 104, and a photo-active layer 106. The semiconductive substrate 102 may include silicon, another type of semiconductive material, or a combination thereof. The insulative layer 104 may include silicon dioxide, another type of insulative material, or a combination thereof.

The photo-active layer 106 may include a germanium-based chalcogenide. Other materials may also be used depending on a particular application. For example, for a full optical spectrum infrared sensitive layer InAs, GaSb, or any NDI-based organic material may be used. For visible solar absorbers GaAs, SiGe, or other organics like P3HT, phthalocyanines, and DPP may be used. For an ultraviolet/blue photoactive layer, GaN, SiC, WS2, rubrene, or polyfluorenes may be used. Other possibilities exist. Some usable materials may include infrared active semiconducting materials, ultraviolet active semiconducting materials, SiGe, GaSb, InAs, MoS₂, WS₂, GaAs, GaN, SiC, an organic-based photoactive semiconductor such as pentacene, rubrene, phthalocyanines, fullerenes, a semiconducting organic polymer including poly-3-hexylthiophene, polyfluorenes, polythiophene derivatives, diketopyrrolopyrrole-based or naphthalene diimide base polymers, another type of photo-active material, or a combination thereof. Further, as used herein the prefix “photo” is not limited to particular bandwidths on the electromagnetic spectrum and may include, but is not limited to, radio waves, microwaves, infrared radiation, visible light, ultraviolet radiation, x-rays, and gamma rays.

The system 100 may further include a first electrode 108 and a second electrode 110. The first electrode 108 and the second electrode 110 may include a conductive material such as tungsten, cadmium, aluminum, another type of conductive metal, or any combination thereof. Together, the semiconductive substrate 102, the insulative layer 104, the photo-active layer 106, the first electrode 108, and the second electrode 110, may constitute an optoelectronic system. Such an optoelectronic system may be described in U.S. Pat. No. 10,700,226, issued Jun. 30, 2020 and entitled “Optically Activated Transistor, Switch, and Photodiode,” the contents of which are incorporated by reference herein in their entirety.

A light source 150 may be configured to selectively apply light 152 to a surface 112 of the photo-active layer 106. The light source 150 may be a light emitting diode (LED) and may emit light in the infrared spectrum, the visible light spectrum, the ultraviolet spectrum, another spectrum of light, or a combination thereof. However, other light sources are possible. Selectively applying the light 152 may include using software or circuit logic to determine durations when the light is on or off (which may be pulses or longer durations, depending on the application), and to determine an intensity of the light 152.

During operation, the light 152 may be applied to the photo-active layer 106. In response to the light, electron displacement may occur within the photo-active layer 106 and the semiconductive substrate 102, resulting in a set of electron-hole pairs 114 to form. This set of electron-hole pairs may be separated by the insulative layer 104. The set of electron-hole pairs 114 may enable an electrical current 116 to exist in response to a voltage difference between the first electrode 108 and the second electrode 110.

The voltage-current characteristics of the system 100 may be analogous to that of a bipolar-junction transistor or a metal-oxide-semiconductor transistor in that, depending on the intensity of the light, in addition to a cutoff region, there may be a linear operating region at lower intensities where a current varies as a function of voltage, and a saturation operating region at higher intensities, where a current is relatively constant as a function of voltage. As explained herein, alterations to the current 116 may be used for substance detection. As such, it may be more effective, for such purposes, to ensure that an intensity of the light 152 is sufficient to cause the system 100 to operate in a saturation mode. In this case the electrical current 116 may be relatively constant with respect to an applied voltage.

A chemical substance 118 may be placed in contact with the surface 112 of the photo-active layer 106. In response to the chemical substance 118, a distribution of the set of electron-hole pairs 114 may be altered. This may result in the electrical current 116 being altered relative to a situation where the chemical substance 118 is not in contact with the surface 112 of the photo-active layer 106. By measuring the electrical current 116 the chemical substance 118 may be detectable. For example, a baseline may be determined through testing. As another example, the system 100 may be duplicated for simultaneous measurements of a test substance and a control substance. Other possible methods of testing and identifying chemical substances are possible.

The system 100 may be advantageous over typical substance testing systems in that it may be field-deployable and capable of determining the presence of a chemical substance in real-time. Other advantages may exist.

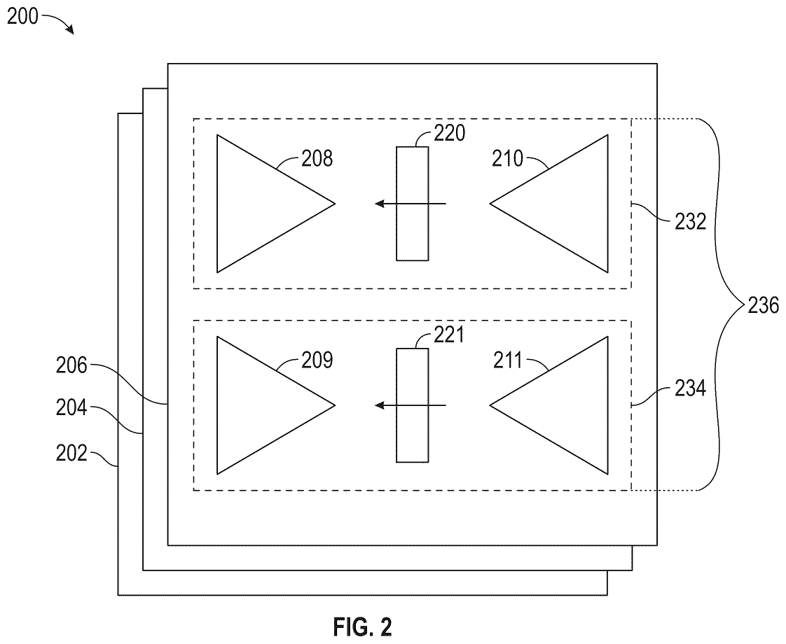

Referring to FIG. 2, a top view of an embodiment of a system 200 is depicted. The system may include a semi-conductive substrate 202, an insulative layer 204, and a photo-active layer 206. The semi-conductive substrate 202, the insulative layer 204, and the photo-active layer 206 may correspond, respectively, to the semi-conductive substrate 102, the insulative layer 104, and the photo-active layer 106 of FIG. 1.

The system 200 may include a set of source-drain-electrode pairs (i.e., a first source electrode 208 may be paired with a first drain electrode 210 and a second source electrode 209 may be paired with a second drain electrode 211), forming a set of optoelectronic semiconductor devices 236. The dotted lines represent a first optoelectronic semiconductor device 232 and a second optoelectronic semiconductor device 234.

The system 200 may include a first channel 220 which may direct a first fluid into contact with the photo-active layer 206 at the first optoelectronic semiconductor device 232 and a second channel 221 which may direct a second fluid into contact with the photo-active layer 206 at the second optoelectronic semiconductor device 234. The test fluid may include the substance to be tested for and the control fluid may omit the substance. In this way a controlled test may be performed.

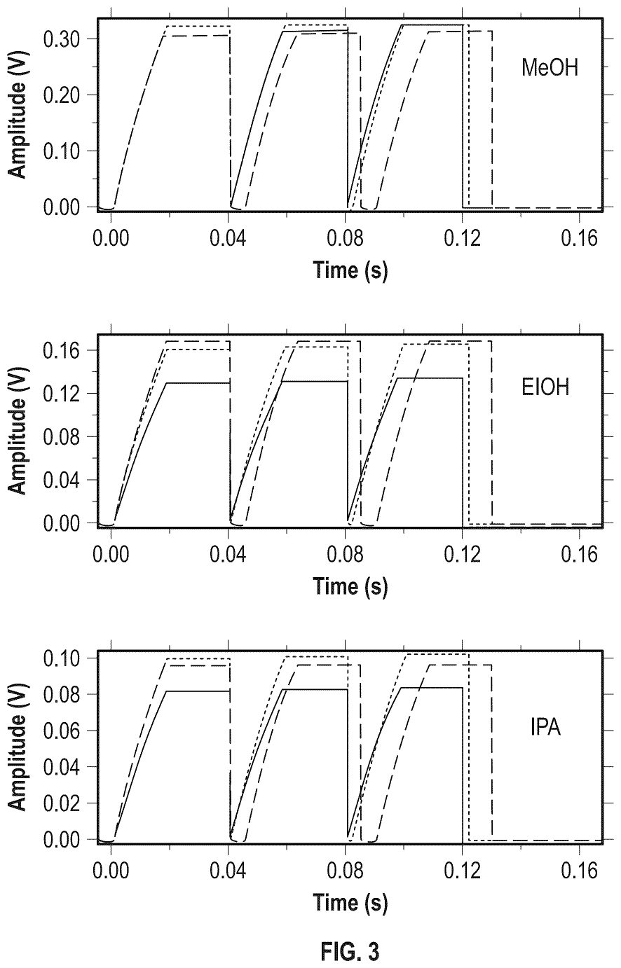

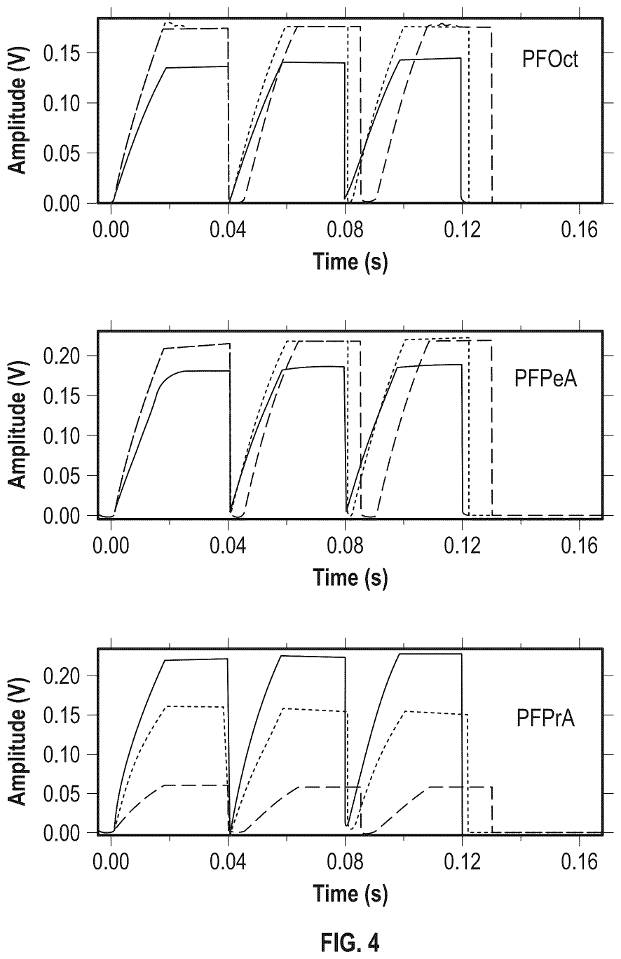

To assist in chemical identification, a set of light pulse sequences may be used while a constant voltage is applied to the drain electrodes 208, 209. This light pulse sequence may be created to capture response time information. The sensor currents 216, 217 will change as a function of time when in the presence of a chemical on the photo-active layer 206. The measured response to the light pulse sequence sets may be varied during the chemical interaction with the gate. In this way, not only is the optoelectronic semiconductor device's initial response time dependence in the presence of chemical measured, but the changes in response time (which may be influenced by the structure of the chemical present and any reactions with the photo-active layer) are measured. This data may then be processed in order to bring out the subtle differences between the chemical structures interacting with the photo-active layer, by use of signal processing steps. FIGS. 3 and 4 depict some such measurements related to various chemicals. FIG. 3 shows response curves related to methanol, ethanol, and isopropyl alcohol. FIG. 4 shows response curves related to perfluorooctanoic, perfluoropentanoic acid, and pentafluoropropionic acid. As can be seen from these graphs, each chemical substance has its own response enabling it to be identified.

Machine learning may be used for chemical identification from the measured data. The data may be pre-processed by removing a direct-current offset from a measurement by averaging a first 100 datapoints and subtracting that number from the entire measurement. The first 100 datapoints may occur prior to the first pulse of light for each sequence. The sample measurement data may then be duplicated into signal digital twin datasets. One twin dataset may be normalized to the first pulse peak steady state value and the other twin dataset is left unnormalized. The unnormalized pre-air baseline corresponding to each substance measurement may be subtracted from both the normalized and unnormalized twin data.

For each signal twin dataset, three regions of each pulse sequence data set may be identified as exhibiting class-distinctive behavior. Curve fitting may be constrained to these data windows, and curve fit parameters may be used to prepare a machine learning data frame. Curve fit parameters for each region may be used to create a ‘delta fit parameter’ for each pulse sequence, and for every fit parameter in each region of each pulse sequence.

After all fit parameters, statistics, and deltas are prepared, a tuned model may be applied to the data. The model may work by directly taking in the dataset of fit parameters and fit parameter deltas (already split into a train dataset and a test dataset), and then iterating through several types of machine learning models (e.g., random forest, extra trees, neural networks, k-nearest neighbors, and logistic regression, or variants thereof).

The best models from the iteration from the previous step may then used to try model stacking (where the predictions from the base models are used as inputs to a second meta-model). The outputs from previously found best models may be combined and used for final predictions (i.e. weighted ensembles created). After all of the different models are tried, ensembles, and stacks, they may be ranked by accuracy to determine a setup that is best suited for the dataset. The setup may then be used to identify the substance.

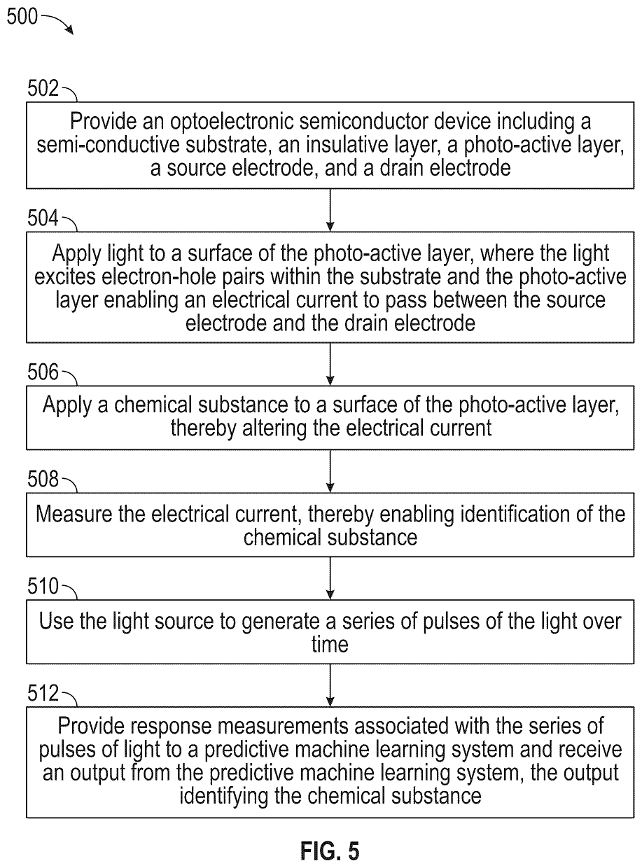

Referring to FIG. 5, an embodiment of a method 500 is depicted. The method 500 may include providing an optoelectronic semiconductor device including a semi-conductive substrate, an insulative layer, a photo-active layer, a source electrode, and a drain electrode, at 502. For example, the system 100 may include a semi-conductive substrate 102, an insulative layer 104, a photo-active layer 106, a source electrode 108, and a drain electrode 110, constituting an optoelectronic semiconductor device.

The method 500 may further include applying light to a surface of the photo-active layer, where the light excites electron-hole pairs within the substrate and the photo-active layer enabling an electrical current to pass between the source electrode and the drain electrode, at 504. For example, the light 152 may be applied to the surface 112 of the photo-active layer 106.

The method 500 may also include applying a chemical substance to a surface of the photo-active layer, thereby altering the electrical current, at 506. For example, the chemical substance 118 may alter the current 116.

The method 500 may include measuring the electrical current, thereby enabling identification of the chemical substance, at 508. For example, the electrical current 116 may be measured to identify the chemical substance 118.

The method 500 may further include using the light source to generate a series of pulses of the light over time, at 510. For example, the light source 150 may be programmed to generate a series of pulses.

The method 500 may also include providing response measurements associated with the series of pulses of light to a predictive machine learning system and receiving an output from the predictive machine learning system, the output identifying the chemical substance, at 512. For example, measurements of the current 116 taken in response to the pulses generated by the light source 150 may identify the chemical substance 118 using machine learning methods.

The method 500 may be advantageous over typical substance testing methods in that it may be field-deployable and capable of determining the presence of a chemical substance in real-time. Other advantages may exist.

Although various embodiments have been shown and described, the present disclosure is not so limited and will be understood to include all such modifications and variations as would be apparent to one skilled in the art.

What is claimed is:

1. A system comprising:
an optoelectronic semiconductor device comprising a semi-conductive substrate, an insulative layer, a photo-active layer, a source electrode, and a drain electrode;
a light source configured to selectively apply light to a surface of the photo-active layer, wherein the light excites electron-hole pairs within the substrate and the photo-active layer enabling an electrical current to pass between the source electrode and the drain electrode, wherein the presence of a chemical substance in proximity to the surface of the photo-active layer alters the electrical current in the presence of the light, and wherein measurement of the electrical current during application of the light enables the chemical substance to be identified.

2. The system of claim 1, wherein a fluid mixture in contact with the photo-active layer includes the substance to be identified.

3. The system of claim 1, wherein the fluid mixture comprises a gas, a liquid, or a combination thereof.

4. The system of claim 1, wherein the chemical substance comprises a perfluoroalkyl substance (PFAS).

5. The system of claim 1, wherein the chemical substance comprises perfluorooctanoic, perfluoropentanoic acid, pentafluoropropionic acid, or a combination thereof.

6. The system of claim 1, wherein the chemical substance is methanal, ethanol, Isopropyl alcohol, lead, or a combination thereof.

7. The system of claim 1, wherein the photo-active layer comprises a germanium-based chalcogenide.

8. The system of claim 1, wherein the photo-active layer comprises SiGe, GaSb, InAs, MoS₂, WS₂, GaAs, GaN, SiC, an organic-based photoactive semiconductor, or a combination thereof.

9. The system of claim 1, wherein the semi-conductive substrate comprises silicon and the insulative layer comprises silicon dioxide.

10. The system of claim 1, wherein the source electrode and the drain electrode comprise a conductive metal including tungsten, cadmium, aluminum, or any combination thereof.

11. The system of claim 1, wherein the intensity of the light source is sufficient to result in a saturation voltage-current response at the optoelectronic semiconductor device.

12. The system of claim 1, wherein the light source is configured to generate a series of pulses of the light over time.

13. A method comprising:
providing an optoelectronic semiconductor device comprising a semi-conductive substrate, an insulative layer, a photo-active layer, a source electrode, and a drain electrode;
applying light to a surface of the photo-active layer, wherein the light excites electron-hole pairs within the substrate and the photo-active layer enabling an electrical current to pass between the source electrode and the drain electrode;
applying a chemical substance to a surface of the photo-active layer, thereby altering the electrical current;
measuring the electrical current, thereby enabling identification of the chemical substance.

14. The method of claim 13, further comprising placing a fluid in contact with the photo-active layer, wherein the fluid includes the electrochemical substance.

15. The method of claim 13, further comprising using the light source to generate a series of pulses of the light over time.

16. The method of claim 15, further comprising providing response measurements associated with the series of pulses of light to a predictive machine learning system and receiving an output from the predictive machine learning system, the output identifying the chemical substance.

17. A system comprising:
a semi-conductive substrate, an insulative layer, a photo-active layer, and a set of source-drain-electrode pairs, forming a set of optoelectronic semiconductor devices;
a light source configured to selectively apply light to a surface of the photo-active layer, wherein the light excites electron-hole pairs within the substrate and the photo-active layer enabling a set of electrical currents to pass through each of the set of the optoelectronic semiconductor devices, wherein the presence of a chemical substance at an optoelectronic semiconductor device of the set of optoelectronic semiconductor devices alters an electrical current associated with the optoelectronic semiconductor device, and wherein measurement of the electrical current enables the chemical substance to be identified.

18. The system of claim 17, wherein the optoelectronic semiconductor device of the set of optoelectronic semiconductor devices is configured to contact a test fluid, and wherein at least another optoelectronic semiconductor device of the set of optoelectronic semiconductor device s is configured to contact a control fluid.

19. The system of claim 17, wherein the chemical substance comprises a perfluoroalkyl substance (PFAS).

20. The system of claim 17, wherein the photo-active layer comprises a germanium-based chalcogenide.
